(19) United States
(12) Patent Application Publication
(10) Pub. No.: US 2005/0090082 A1
(43) Pub. Date: Apr. 28, 2005

(54) Method and system for improving performance of MOSFETs

(75) Inventors: Seetharaman Sridhar, Richardson, TX (US); Majid M. Mansoori, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/695,307

(22) Filed: Oct. 28, 2003

(51) Int. Cl. C30B 1/00

(52) U.S. Cl. 438/508

(57) ABSTRACT

According to one embodiment of the invention, a method for forming MOSFETs includes providing a substrate having a source region, a gate region, and a drain region, forming a silicon-germanium layer in each of the source and drain regions, forming, in the substrate, a source in the source region and a drain in the drain region, forming a silicon layer outwardly from the silicon-germanium layer in each of the source and drain regions, and forming a silicide layer in each of the source and drain regions.

### TECHNICAL FIELD OF THE INVENTION

The present invention relates generally to the field of semiconductor devices and, more particularly, to a method and system for improving performance of metal-oxide-semiconductor field effect transistors (“MOSFETs”).

### BACKGROUND OF THE INVENTION

Modern electronic equipment, such as televisions, radios, cell phones, and computers are generally constructed of solid state devices. Solid state devices include transistors, capacitors, resistors and the like. One type of transistor is a metal oxide semiconductor field effect transistor (MOSFET), such as NMOS, PMOS, or CMOS transistors. MOSFETs may be used in a myriad of electronic devices.

Increasingly, MOSFETs are made smaller to reduce the size of electronic equipment. In addition, use of the devices in, for example, high performance logic requires faster operational speed. One way to increase drive current in MOSFETs is to utilize Silicon-Germanium (SiGe) epitaxial layers in the source and drain regions to introduce compressive stress in the channel. However, subsequent salicidation over the SiGe epitaxial layers may counteract the benefits by increasing source/drain resistances.

### SUMMARY OF THE INVENTION

According to one embodiment of the invention, a method for forming MOSFETs includes providing a substrate having a source region, a gate region, and a drain region, forming a silicon-germanium layer in each of the source and drain regions, forming, in the substrate, a source in the source region and a drain in the drain region, forming a silicon layer outwardly from the silicon-germanium layer in each of the source and drain regions, and forming a silicide layer in each of the source and drain regions.

Embodiments of the invention provide a number of technical advantages. Embodiments of the invention may include all, some, or none of these advantages. According to one embodiment, mosfet performance is improved by reducing the source/drain resistances that exist after the salicidation process, which results in faster semiconductor devices. In one embodiment, such advantages are achieved by capping the SiGe layers in the source and drain regions with a thin layer of silicon. One advantage of this capping step is that it may be implemented as a drop-in.

Other technical advantages are readily apparent to one skilled in the art from the following figures, descriptions, and claims.

### BRIEF DESCRIPTION OF THE DRAWINGS

For a more complete understanding of the invention, and for further features and advantages, reference is now made to the following description, taken in conjunction with the accompanying drawings, in which:

FIGS. 1A-1D are a series of cross-sectional views illustrating various manufacturing stages of a MOSFET in accordance with one embodiment of the present invention.

### DETAILED DESCRIPTION OF EXAMPLE EMBODIMENTS OF THE INVENTION

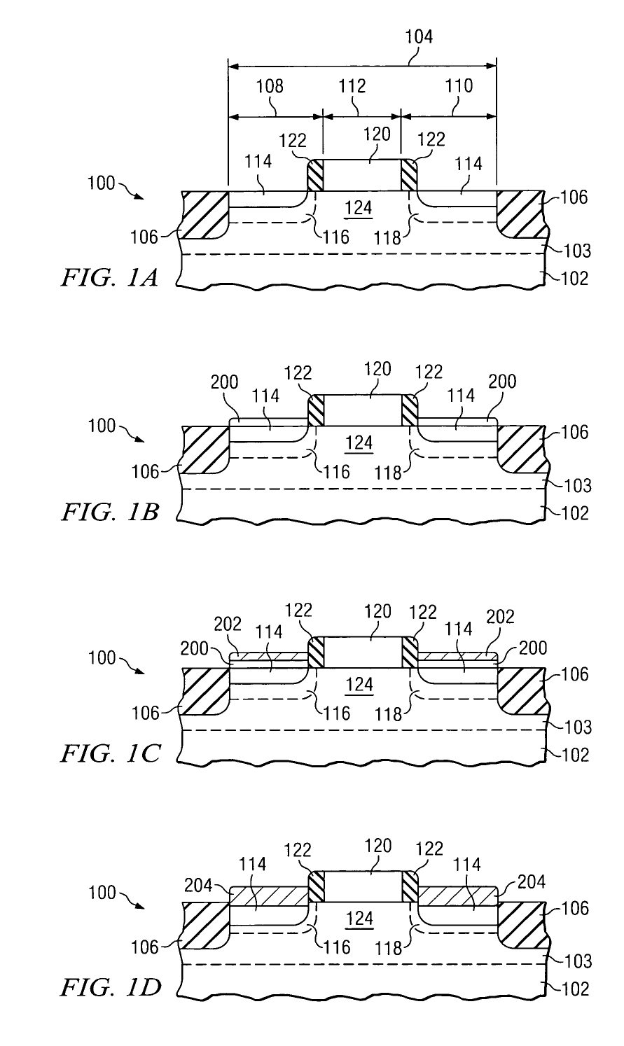

Example embodiments of the present invention and their advantages are best understood by referring now to FIGS. 1A through 1D of the drawings, in which like numerals refer to like parts.

FIGS. 1A-1D are a series of cross-sectional views illustrating various manufacturing stages of a MOSFET 100 in accordance with one embodiment of the present invention. MOSFET 100, as used throughout the following detailed description, represents a partially completed MOSFET, such as an NMOS, PMOS, CMOS, or other suitable semiconductor device. In the illustrated embodiment, MOSFET 100 includes a substrate 102 having a well 103 formed therein and an active area 104 disposed between a pair of isolation regions 106. Active area 104 includes a source region 108, a gate region 112, and a drain region 110. Source region 108 includes a silicon-germanium (SiGe) layer 114 formed either within substrate 102 or outwardly from substrate 102 and a source 116 formed in substrate 102. Drain region 110 also includes SiGe layer 114 formed either within substrate 102 or outwardly from substrate 102 and a drain 118 formed in substrate 102. Gate region 112 includes a gate 120 formed outwardly from substrate 102 and a pair of side walls 122 formed on either side of gate 120.

Substrate 102 may be formed from any suitable semiconductor material, such as silicon. For example, substrate 102 may be a silicon wafer, a silicon wafer with previously fabricated embedded devices, an epitaxial layer grown on a wafer, a semiconductor on insulation (SOI) system, or other suitable substrates having any suitable crystal orientation. Substrate 102 includes well 103 formed therein that may be any suitable N-type or P-type well, depending on the type of semiconductor device being fabricated.

Isolation regions 106 may be any suitable shallow or deep trench isolation regions formed from any suitable dielectric material, such as oxide, that defines active area 104 therebetween. Within active area 104 is where the transistor elements are fabricated for MOSFET 100. As described above, both source region 108 and drain region 110 include SiGe layers 114 that are formed within substrate 102 in the illustrated embodiment. In other embodiments, SiGe layers 114 may be formed outwardly from substrate 102. SiGe layers 114 may have any suitable thickness depending on the size of the particular transistor being fabricated; however, in one embodiment, the thickness of SiGe layers 114 is between approximately 200 angstroms and 300 angstroms. In one embodiment, SiGe layers 114 are formed as epitaxial layers. One function of SiGe layers 114 is to increase the compressive stress within a channel 124 disposed between source 116 and drain 118 and beneath gate 120. This aids in hole mobility for MOSFET 100. Both source 116 and drain 118 may be formed using any suitable techniques used in semiconductor processing, such as ion implantation. For example, if MOSFET 100 is a P-type transistor, then boron or other suitable P-type dopant may be implanted during the ion implantation process to form source 116 and drain 118. If MOSFET 100 is an N-type transistor, then arsenic, phosphorous, antimony, or other suitable N-type dopant may be implanted in substrate 102 to form source 116 and drain 118.

Gate 120 may be formed using any suitable growth and/or deposition techniques used in semiconductor processing and may be formed from any suitable material, such as polysilicon or a suitable metal. Sidewalls 122 may also be formed using any suitable growth and/or deposition techniques used in semiconductor processing and may be formed from any suitable dielectric material, such as oxide, nitrite or other suitable materials.

As described above, SiGe layers 114 are utilized to induce compressive stresses within channel 124 to increase the drive current in MOSFET 100. However, subsequent salicidation over the SiGe layers 114 may counteract the benefits of this increased I_{drive} by increasing source/drain resistances. To address this problem, SiGe layers 114 are capped with a layer of silicon before the salicidation process, as illustrated below in conjunction with FIG. 1B.

FIG. 1B illustrates a silicon layer 200 formed outwardly from SiGe layers 114. Silicon layer 200 may be formed using any suitable growth and/or deposition techniques used semiconductor processing. In one embodiment, a thickness of silicon layer 200 is between approximately 25 angstroms and 150 angstroms. In a particular embodiment, the thickness is approximately 75 angstroms. Capping SiGe layers 114 with silicon layer 200 decreases the source/drain resistances that would have occurred if the salicidation process had taken place directly over SiGe layers 114. This is because the materials used for the salicidation process react with SiGe differently than silicon.

Referring to FIG. 1C, a reactive metal layer 202 is disposed outwardly from silicon layer 200 for the salicidation process. Reactive metal 202 may be formed using any suitable growth and/or deposition techniques used in semiconductor processing. A thickness of reactive metal layer 202 may be any suitable thickness. In addition, the type of material used for reactive metal layer 202 may include titanium, cobalt, nickel, tungsten, or other suitable reactive metal. Due to process conditions within a suitable processing chamber, such as a CVD processing chamber, reactive metal layer 202 reacts with silicon layer 200 to form a salicide layer 204, as shown below in conjunction with FIG. 1D.

Referring to FIG. 1D, salicide layer 204 is shown to be formed outwardly from SiGe layers 114. Depending on the thicknesses of SiGe layer 114, silicon layer 200, reactive metal 204, and the process conditions within the processing chamber, salicide layer 204 may react with only a portion of silicon layer 200, all of silicon layer 200, or all of silicon layer plus a portion of SiGe layers 114. Salicide layer 204 functions to provide good contact with source 116 and drain 118 from MOSFET 100 in order to facilitate good hole mobility in channel 124. Because reactive metal layer 202 reacts mainly with silicon layer 200 instead of just with SiGe layers 114, the source/drain resistances are reduced, thereby resulting in a better performing MOSFET. Another advantage of capping SiGe layers 114 with silicon layer 200 is that the capping step may be implemented as a drop-in, as opposed to trying to tailor the salicidation process.

Although embodiments of the invention and their advantages are described in detail, a person skilled in the art could make various alterations, additions, and omissions without departing from the spirit and scope of the present invention as defined by the appended claims.

1. A method for forming MOSFETs, comprising:
providing a substrate having a source region, a gate region, and a drain region;
forming a silicon-germanium layer in each of the source and drain regions;
forming, in the substrate, a source in the source region and a drain in the drain region;
forming a silicon layer outwardly from the silicon-germanium layer in each of the source and drain regions; and
forming a silicide layer in each of the source and drain regions.

2. The method of claim 1, wherein forming the silicide layer comprises:
depositing a reactive metal outwardly from the silicon layer in each of the source and drain regions;
reacting the reactive metal with at least the silicon layer; and
selectively removing non-reacted reactive metal from the substrate.

3. The method of claim 2, wherein the reactive metal is selected from the group consisting of titanium, cobalt, nickel, and tungsten.

4. The method of claim 1, wherein forming the silicide layer comprises:
depositing a reactive metal outwardly from the silicon layer in each of the source and drain regions;
reacting the reactive metal with the silicon layer and a portion of the silicon-germanium layer; and
selectively removing non-reacted reactive metal from the substrate.

5. The method of claim 4, wherein the reactive metal is selected from the group consisting of titanium, cobalt, nickel, and tungsten.

6. The method of claim 1, wherein forming the silicon-germanium layer in each of the source and drain regions comprises forming, in the substrate, the silicon-germanium layer in each of the source and drain regions.

7. The method of claim 1, wherein forming the silicon-germanium layer in each of the source and drain regions comprises forming, outwardly from the substrate, the silicon-germanium layer in each of the source and drain regions.

8. The method of claim 1, wherein the silicon layer has a thickness between approximately 25 Å and 150 Å.

9. The method of claim 1, wherein the silicon layer has a thickness of approximately 75 Å.

10. The method of claim 1, wherein the silicon-germanium layer has a thickness between approximately 200 Å and 300 Å.

11. The method of claim 1, wherein the silicon-germanium layer is an epitaxial layer.

12. A method for forming MOSFETs, comprising:
providing a substrate having a source region, a gate region, and a drain region;
forming, in the substrate, an epitaxial silicon-germanium layer in each of the source and drain regions;
forming, in the substrate, a source in the source region and a drain in the drain region;
forming a silicon layer outwardly from the silicon-germanium layer in each of the source and drain regions, the silicon layer having a thickness between approximately 25 Å and 150 Å;
depositing a reactive metal outwardly from the silicon layer in each of the source and drain regions;
reacting the reactive metal with at least a portion of the silicon layer; and
selectively removing non-reacted reactive metal from the substrate to form a silicide layer in each of the source and drain regions.

13. The method of claim 12, wherein the reactive metal is selected from the group consisting of titanium, cobalt, nickel, and tungsten.

14. The method of claim 12, wherein reacting the reactive metal with at least a portion of the silicon layer comprises reacting the reactive metal with the whole silicon layer and a portion of the silicon-germanium layer.

15. The method of claim 12, wherein the silicon layer has a thickness of approximately 75 Å.

16. The method of claim 12, wherein the silicon-germanium layer has a thickness between approximately 200 Å and 300 Å.

17. A system for forming MOSFETs, comprising:
a substrate having a source region, a gate region, and a drain region;
an epitaxial silicon-germanium layer formed in each of the source and drain regions;
a source formed in the source region;
a drain formed in the drain region;
a silicon layer disposed outwardly from the silicon-germanium layer in each of the source and drain regions; and
a reactive metal layer formed in each of the source and drain regions.

18. The system of claim 18, wherein the silicon-germanium layer in each of the source and drain regions is formed within the substrate.

19. The system of claim 18, wherein the silicon-germanium layer in each of the source and drain regions is formed outwardly from the substrate.

20. The system of claim 18, wherein the silicon layer has a thickness between approximately 25 Å and 150 Å.
